(19) United States
(12) Patent Application Publication
(10) Pub. No.: US 2022/0316055 A1
(43) Pub. Date: Oct. 6, 2022

(54) LOW TEMPERATURE DEPOSITION PROCESS

(71) Applicant: ENTEGRIS, INC., Billerica, MA (US)

(72) Inventors: Han Wang, Cromwell, CT (US); Bryan C. Hendrix, Danbury, CT (US)

(21) Appl. No.: 17/708,999

(22) Filed: Mar. 30, 2022

Related U.S. Application Data
(60) Provisional application No. 63/168,090, filed on Mar. 30, 2021.

(51) Int. Cl. C23C 16/34; C23C 16/455

(52) U.S. Cl. CPC C23C 16/34; C23C 16/45527

(57) ABSTRACT

The invention provides a process for the deposition of titanium silicon nitride (TiSiN) films onto a substrate, such as a substrate surface on a microelectronic device. Surprisingly, the process can be run at relatively low temperatures for the silicon precursors described herein.

### TECHNICAL FIELD

This invention generally relates to methodology for forming certain thin films on microelectronic device substrates. In particular, the invention relates to methodology for the deposition of TiSiN films.

### BACKGROUND

In the manufacturing of integrated circuits, titanium nitride has been of considerable interest given its relatively low resistivity and compatibility with CMOS (complementary metal oxide semiconductor) processes. Accordingly, titanium nitride is often used as a liner barrier and can be deposited over a silicon substrate. Such titanium nitride layers may be used as a barrier layer to inhibit the diffusion of metals into regions underlying the barrier layer. A conductive metal layer, such as a copper-containing layer or a tungsten containing layer, is usually deposited over the titanium nitride layer. The titanium layer may be formed by a chemical vapor deposition (CVD) process, an atomic layer deposition (ALD) process, and/or a physical vapor deposition (PVD) process. For example, the titanium nitride layer may be formed by reacting titanium tetrachloride with a reducing agent such as ammonia during a CVD process and the titanium nitride layer may be formed by reacting titanium tetrachloride with ammonia in a CVD process. Thereafter, the conductive material may be deposited onto the microelectronic device substrate. See, for example, U.S. Pat. No. 7,838,441. The deposition of materials such as titanium nitride and titanium silicon nitride are however plagued with difficulties in the initiation of the deposition on the microelectronic device substrate, and the building of film thickness based on the number of deposition sequences is relatively poor in the so-called initial, non-linear growth region. See, for example, “Growth Mechanism and Continuity of Atomic Layer Deposited TiN films on Thermal SiO₂”, A. Satta, et al., Journal of Applied Physics, Volume 92, Number 12, pp. 7641-7646 (2002).

In some microelectronic device substrates, films must be deposited at lower temperatures, for example 250° C. to 450° C. At such lower temperatures, it is particularly difficult to incorporate silicon into titanium silicon nitride films due to reduced reactivity activity of silicon precursors at these lower temperatures. Thus, there is a need for improved methodologies for the deposition of titanium-containing films, in particular, titanium silicon nitride, wherein the deposition is conducted at lower temperatures to accommodate certain microelectronic device substrates.

### SUMMARY

In summary, the invention provides a process for the deposition of titanium silicon nitride (TiSiN) films onto a substrate, such as a substrate surface on a microelectronic device. Surprisingly, the process can be run at relatively low temperatures for the silicon precursors described herein. In one embodiment of the process, certain silicon precursors are introduced in the reaction zone, followed by titanium chloride or titanium iodide, followed by a nitrogen-containing reducing gas. Optional purge steps after the introduction of each precursor with an inert gas may be utilized. At these relatively low temperatures the process can achieve, for example, a TiSiN film of about 30% Si, using silicon precursors such as bis-t-amyl ethylene silylene (TAS). The doping level of silicon in the resulting TiSiN films can be adjusted higher or lower (i.e., “tuned”) by utilization of more or fewer titanium nitride sub-cycles in the process (i.e., the titanium chloride or titanium iodide followed by a nitrogen-containing reducing gas), thereby lowering the overall relative percentage of silicon present in the film.

### BRIEF DESCRIPTION OF THE DRAWINGS

FIG. 1 is a graph of silicon nitride thickness in angstroms versus number of silicon nitride deposition sub-cycles, wherein the sub-cycle is defined by the introduction of TAS and inert gas. Thickness is measured by X-ray fluorescence spectroscopy (XRF).

FIG. 2 is a graph of titanium nitride thickness in angstroms versus number of titanium nitride sub-cycles, wherein the sub-cycle is defined by the introduction of TiCl₄, inert gas, and nitrogen containing reducing gas (NH₃).

FIG. 3 is a graph of Si % as a function of TiSiN film thickness in angstroms using TAS, TiCl₄ and NH₃ (combining the thickness of SiN and TiN in FIGS. 1 and 2).

FIG. 4 is a graph of sheet resistance as a function of TiSiN film thickness in angstroms using TAS, TiCl₄, and NH₃ (combining the thickness of SiN and TiN in FIGS. 1 and 2).

FIG. 5 is crystallinity comparison between pure TiN and TiSiN with similar thicknesses. X-ray diffraction (XRD) is used for this measurement. Pure TiN is polycrystalline with characteristic peaks, but TiSiN is amorphous without any noticeable peaks. TiN is deposited using TiCl₄ and NH₃. TiSiN is deposited using TAS, TiCl₄, and NH₃.

FIG. 6 is a graph of silicon nitride thickness in angstroms versus number of silicon nitride sub-cycles, wherein the sub-cycle is defined by the introduction of SiI₂H₂ and inert gas.

FIG. 7 is a graph of titanium nitride thickness in angstroms versus number of titanium nitride sub-cycles, wherein the sub-cycle is defined by the introduction of TiCl₄, inert gas, and nitrogen containing reducing gas (NH₃).

FIG. 8 is a graph of Si % as a function of TiSiN film thickness in angstroms using SiI₂H₂, TiCl₄ and NH₃ (combining the thickness of SiN and TiN in FIGS. 6 and 7).

FIG. 9 is a graph of sheet resistance as a function of TiSiN film thickness in angstroms using SiI₂H₂, TiCl₄, and NH₃ (combining the thickness of SiN and TiN in FIGS. 6 and 7).

### DETAILED DESCRIPTION OF THE INVENTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a process for depositing a titanium silicon nitride (TiSiN) film on a microelectronic device substrate in a reaction zone, which comprises:
introducing compounds A, B, and C, individually, into the reaction zone under pulsed vapor deposition conditions to provide a pulse sequence, wherein the reaction zone is about 250° C. to about 450° C.; each compound optionally followed by a purge step with an inert gas, and wherein A is chosen from bis-t-amyl ethylene silylene, SiI₂H₂, and SiI₄; B is chosen from TiCl₄ and TiI₄; and C is a nitrogen-containing reducing gas, and repeating the pulse sequence until a desired thickness of the film has been deposited.

In one embodiment, the thickness of the titanium silicon nitride film is at least about 10 Å. In other embodiments, the thickness of the titanium silicon nitride film is at least about 20 Å; at least about 30 Å; at least about 40 Å; at least about 50 Å; at least about 60 Å; at least about 70 Å; at least about 80 Å; at least about 90 Å; or at least about 100 Å.

As a consequence of the process of the invention, the relative level of amorphous character in the film is increased—i.e., the relative crystallinity is reduced

In the process of the invention, the sequence of B to C (or “B-C”), i.e., titanium chloride or titanium iodide, followed by a nitrogen-containing gas, is referred to herein as the TiN (titanium nitride) sub-cycle. As noted above, if a lower overall silicon percentage in the resulting TiSiN film is desired, this TiN sub-cycle may be repeated in the deposition process of the invention in a pre-determined quantity, thereby increasing the amount of titanium nitride in the film which thus results in an overall concomitant reduction in silicon in the film as titanium nitride is deposited. Thus, in one embodiment, the pulse sequence is A, followed by B, followed by C, with optional purge steps between introduction of A, B, and C, followed by at least one titanium nitride sub-sequence of B to C, which sub-sequence(s) can be introduced between each A to B to C pulse sequence, or can be repeated one after another, i.e., B to C, followed by B to C, etc., in any combination of sequences, until an overall ratio of A to B to C pulse sequences to C to B sub-cycles is adjusted in a pre-determined manner (based on empirical experience) which thus increases the titanium nitride layer formation, and reduction of the corresponding overall silicon percentage in the titanium silicon nitride (TiSiN) film.

Accordingly, in one embodiment, the pulsed vapor deposition conditions comprise a plurality of pulse sequences, wherein the pulse sequence comprises a pulse of A, followed by a pulse of B, followed by a pulse of C, each pulse optionally followed by a purge with an inert gas. In another embodiment, the invention provides the above process, further comprising introduction of B and C to provide a titanium nitride sub-cycle, each of B and C optionally followed by a purge with an inert gas. In this fashion, a titanium silicon nitride film of about 5 to about 50 weight percent of silicon may be formed, based on the desired percentage of silicon and a predetermined number of titanium nitride sub-cycles relative to the A to B to C pulse sequences utilized in the vapor phase deposition. In certain embodiments, the percentage of silicon in the resulting film is about 5 to about 10; about 10 to about 15; about 15 to about 20; about 20 to about 25; about 25 to about 30; about 30 to about 35; about 35 to about 40; about 40 to about 45; about 45 to about 50; about 10 to about 40; or about 15 to about 35 weight percent.

In certain embodiments, A is bis-t-amyl ethylene silylene, B is TiCl₄, and C is ammonia. In other embodiments, A is SiI₂H₂. In other embodiments, A is SiI₄.

In certain embodiments, the pulse time (i.e., duration of precursor (A, B, and C) exposure to the substrate) for the compounds depicted above ranges between about 0.1 and 60 seconds. When a purge step is utilized, the duration of said purge step is from about 1 to 60 seconds, 1 to 4 seconds or 1 to 2 seconds, depending on the particular tool utilized and depending on the identity of the precursor compound, as well as the substrate on which deposition occurs. In other embodiments, the pulse time for each compound's introduction into the reaction zone ranges from about 0.1 to 60 seconds or 20 to 40 seconds, again depending upon the tool utilized. In other embodiments, the pulse time for each compound ranges from about 5 to about 10 seconds.

In one embodiment, the vapor deposition conditions comprise a temperature of about 250° C. to about 450° C. In certain embodiments, the vapor deposition conditions comprise a pressure of about 0.5 to about 1000 Torr, or 1 to 30 Torr. In another embodiment, the vapor deposition conditions comprise a temperature of about 350° to about 450° C. Choices of particular temperature and pressure is dependent upon the particular tool utilized for the deposition, the identity of compound A, B, and C, as well as the substrate on which deposition occurs. In any event, the process of the invention makes possible the formation of titanium silicon nitride films at surprisingly low temperatures.

The processes which can be employed for forming high-purity thin metal, for example, titanium-containing films include any suitable thermal vapor deposition technique, such as digital or pulsed CVD or ALD. Such vapor deposition processes can be utilized to form titanium silicon nitride films on at least one substrate surface of microelectronic devices to form films having a thickness of from about 10 angstroms to about 2000 angstroms.

In the process of the invention, the compounds above may be reacted with the desired microelectronic device substrate in any pulsing regime, for example, in a single wafer CVD, ALD chamber, or in a furnace containing multiple wafers.

Alternately, the process of the invention can be conducted as an ALD or ALD-like process. As used herein, the terms “ALD or ALD-like” refers to processes such as (i) each reactant is introduced sequentially into a reactor such as a single wafer ALD reactor, semi-batch ALD reactor, or batch furnace ALD reactor, or (ii) each reactant, is exposed to the substrate or microelectronic device surface by moving or rotating the substrate to different sections of the reactor and each section is separated by an inert gas curtain, i.e., spatial ALD reactor or roll to roll ALD reactor.

As used herein, the term “nitrogen-containing reducing gas” includes gases chosen from hydrazine (N₂H₄), methyl hydrazine, t-butyl hydrazine, 1,1-dimethylhydrazine, 1,2-dimethylhydrazine, and NH₃.

The deposition methods disclosed herein may involve one or more purge gases. The purge gas, which is used to purge away unconsumed reactants and/or reaction by-products, is an inert gas that does not react with the precursors. Exemplary purge gases include, but are not limited to, argon, nitrogen, helium, neon, and mixtures thereof. In certain embodiments, a purge gas such as Ar is supplied into the reactor at a flow rate ranging from about 10 to about 2000 sccm for about 0.1 to 1000 seconds, thereby purging the unreacted material and any by-product that may remain in the reactor. Similarly, such inert gases may be used as carrier gases for the various precursors described above. Concentration and flow rate may vary depending upon the particular tool utilized.

Energy is applied to the precursor compounds and reducing gas, or combination thereof to induce reaction and to form the metal nitride-containing film on the microelectronic device substrate. Such energy can be provided by thermal or pulsed thermal methods.

As used herein, the term “microelectronic device” corresponds to semiconductor substrates, including 3D NAND structures, flat panel displays, and microelectromechanical systems (MEMS), manufactured for use in microelectronic, integrated circuit, or computer chip applications. It is to be understood that the term “microelectronic device” is not meant to be limiting in any way and includes any substrate that includes a negative channel metal oxide semiconductor (nMOS) and/or a positive channel metal oxide semiconductor (pMOS) transistor and will eventually become a microelectronic device or microelectronic assembly. Such microelectronic devices contain at least one substrate, which can be chosen from, for example, silicon, SiO₂, Si₃N₄, aluminum oxide, zirconium oxide, hafnium oxide, and other high-K oxides, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, germanium, germanium-containing, boron-containing, Ga/As, a flexible substrate, porous inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

### EXAMPLES

### Example 1— Preparation of TiSiN Film at 350° C.

The titanium silicon nitride film was deposited by an ALD process using titanium tetrachloride (TiCl₄), TAS*, and ammonia as precursor compounds. Each deposition cycle was conducted according to the sequence below:
1. 0.2 second pulse of TAS
2. 10 second pulse of Argon
3. 0.2 second pulse of TiCl₄
4. 10 second pulse of Argon
5. 1 second pulse of NH₃.
   *TAS (bis-t-amyl ethylene silylene) is an organosilylene

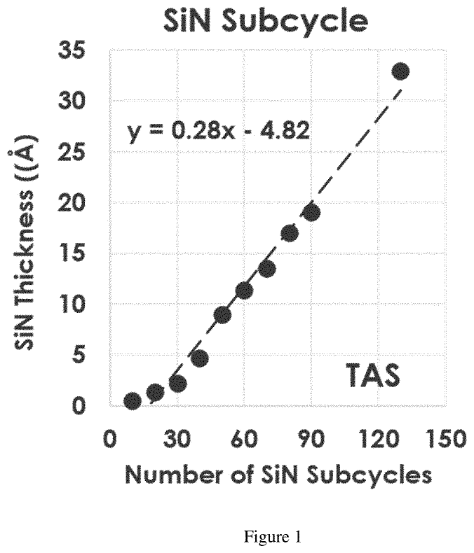

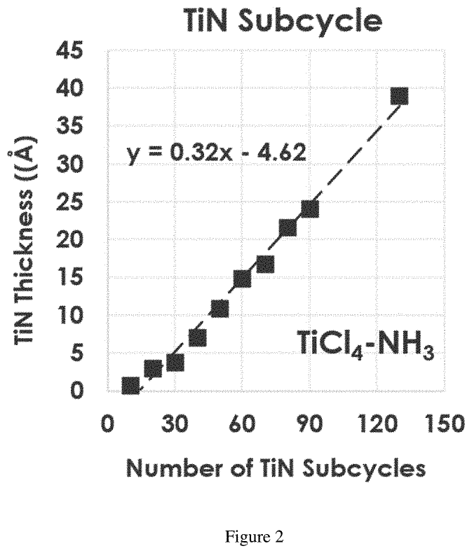

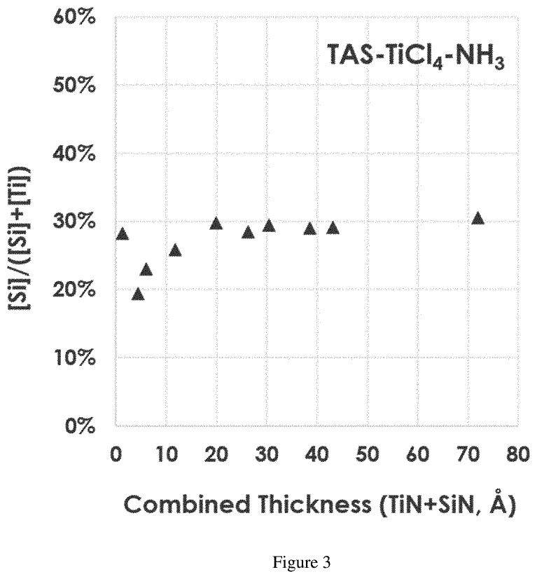

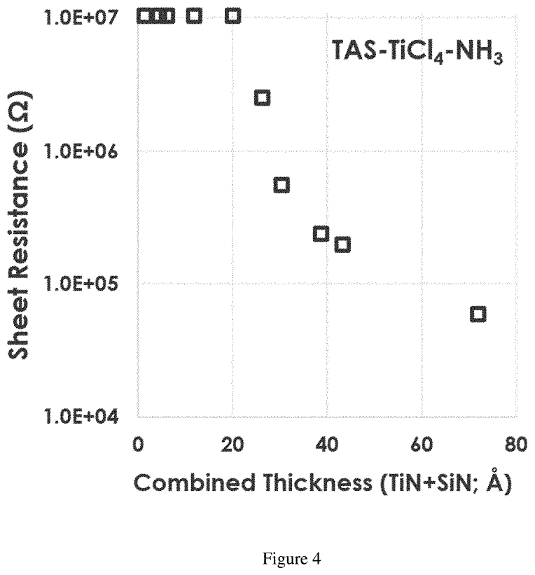

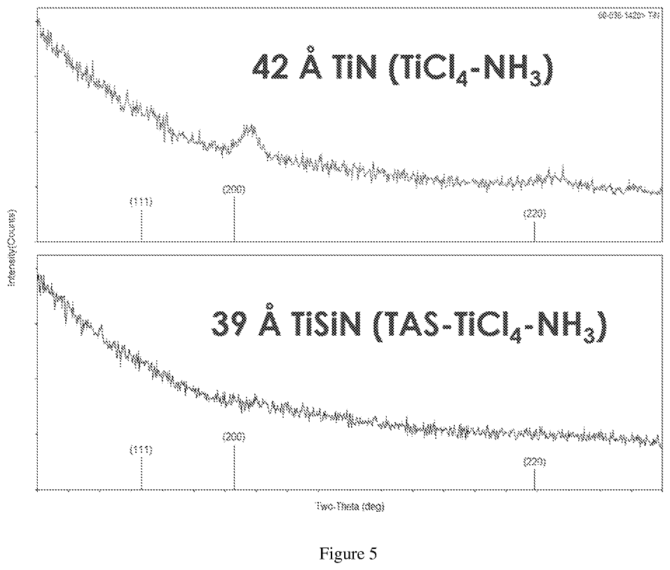

As can be seen from the data presented in FIGS. 1 and 2, there was a nucleation delay for both TAS and TiCl₄ when the individual silicon nitride and titanium nitride subcycles were less than 20; subsequently, approximate linear growth is exhibited for both subcycles. As shown in FIGS. 3 and 4, the tested ratio of 1:1 leads to a uniform Si doping level around 30% for TiSiN films with thickness above 20 Å, which also becomes conducting. By adding more TiN subcycles, we can easily reduce Si doping level to a desired target. As illustrated by FIG. 5, measurement of a 42 Å titanium nitride film was polycrystalline and measurement of a 39 Å titanium silicon nitride film was amorphous.

### Example 2—Preparation of TiSiN Film at 350° C.

The titanium silicon nitride film was deposited by an ALD process using titanium tetrachloride (TiCl₄), SiI₂H₂, and ammonia as precursor compounds. Each deposition cycle was conducted according to the sequence below:
1. 0.2 second pulse of SiI₂H₂
2. 10 second pulse of Argon
3. 0.2 second pulse of TiCl₄
4. 10 second pulse of Argon
5. 1 second pulse of NH₃.

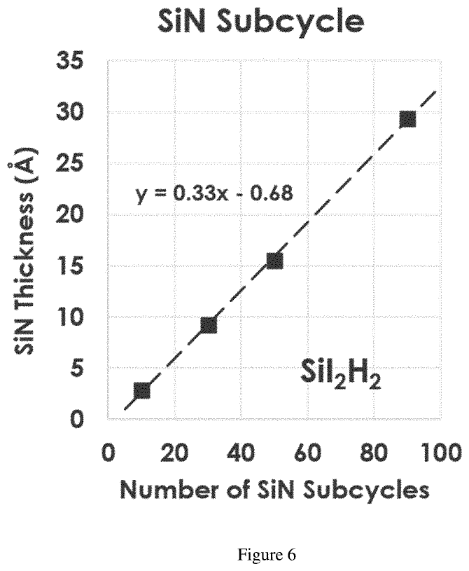

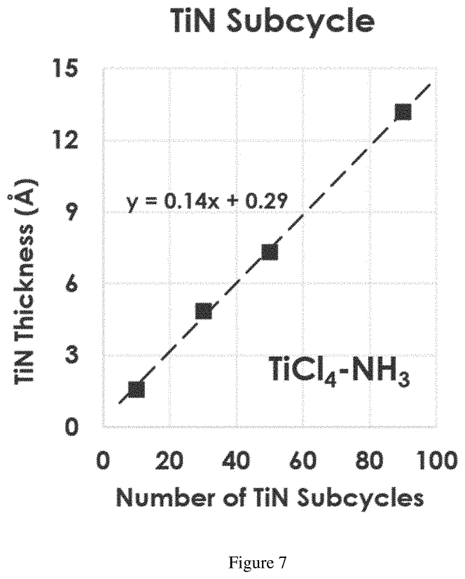

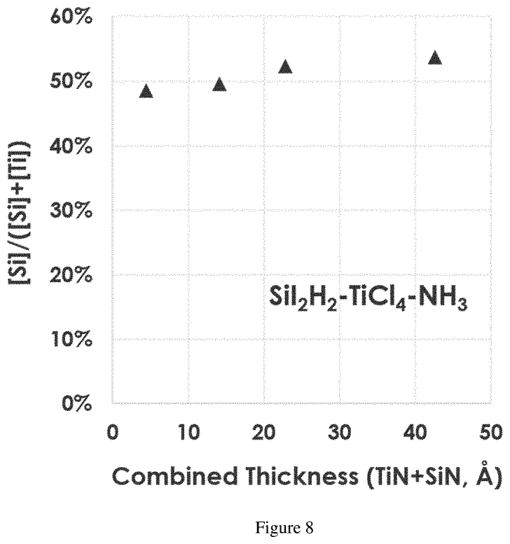

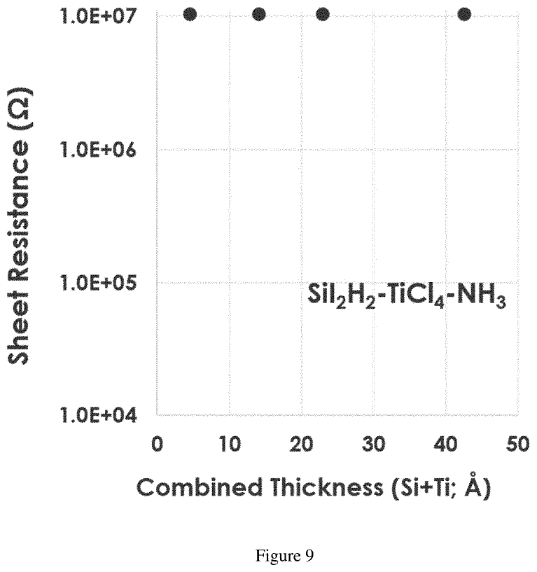

As can be seen from the data presented in FIGS. 6 and 7, there was no nucleation delay for both SiI₂H₂ and TiCl₄ for the individual silicon nitride and titanium nitride sub-cycles with linear growth. As shown in FIGS. 8 and 9, the tested ratio of 1:1 leads to a uniform Si doping level around 50% for TiSiN films, which is insulating. By adding more TiN sub-cycles, we can easily reduce Si doping level to a desired target percentage.

Aspects

In a first aspect, the invention provides a process for depositing a titanium silicon nitride film on a microelectronic device substrate in a reaction zone, which comprises:
introducing compounds A, B, and C, individually, into the reaction zone under pulsed vapor deposition conditions to provide a pulse sequence, wherein the reaction zone is about 250° C. to about 450° C.; each compound optionally followed by a purge step with an inert gas, and wherein A is chosen from bis-t-amyl ethylene silylene, SiI₂H₂, and SiI₄; B is chosen from TiCl₄ and TiI₄; and C is a nitrogen-containing reducing gas, and repeating the pulse sequence until a desired thickness of the film has been deposited.

In a second aspect, the invention provides the process of the first aspect, wherein the thickness of the titanium silicon nitride film is at least about 10 Å.

In a third aspect, the invention provides the process of the first aspect, wherein the thickness of the titanium silicon nitride film is at least about 20 Å.

In a fourth aspect, the invention provides the process of the first aspect, wherein the thickness of the titanium silicon nitride film is at least about 30 Å.

In a fifth aspect, the invention provides the process of the first aspect, wherein the pulsed vapor deposition conditions comprise a plurality of pulse sequences, wherein the pulse sequence comprises a pulse of A, followed by a pulse of B, followed by a pulse of C, each pulse optionally followed by a purge step with an inert gas.

In a sixth aspect, the invention provides the process of any one of the first through the fifth aspects, wherein A is bis-t-amyl ethylene silylene.

In a seventh aspect, the invention provides the process of any one of the first through the fifth aspects, wherein A is SiI₂H₂.

In an eighth aspect, the invention provides the process of any one of the first through the seventh aspects, wherein B is titanium tetrachloride.

In a ninth aspect, the invention provides the process of any one of the first through the eighth aspects, wherein the nitrogen-containing reducing gas is chosen from ammonia; hydrazine; 1,1-dimethyl hydrazine; and 1,2-dimethyl hydrazine.

In a tenth aspect, the invention provides the process of any one of the first through the ninth aspects, wherein the nitrogen-containing reducing gas is ammonia.

In an eleventh aspect, the invention provides the process of the any one of the first through the fourth aspects, wherein the pulsed vapor deposition conditions further comprise introduction of B and C to provide a titanium nitride sub-cycle, each of B and C optionally followed by a purge with an inert gas.

The twelfth aspect, the invention provides the pulsed vapor deposition conditions comprise a plurality of pulse sequences, wherein the pulse sequence comprises a pulse of A, followed by a pulse of C, followed by a pulse of B, followed by a pulse of C, each pulse optionally followed by a purge step with an inert gas

In a thirteenth aspect, the invention provides the process of the fifth aspect, further comprising introduction of B and C to provide a titanium nitride sub-cycle, each of B and C optionally followed by a purge with an inert gas.

In a fourteenth aspect, the invention provides the process of the twelfth aspect, wherein B is introduced followed by C.

In a fifteenth aspect, the invention provides the process of any one of the eleventh through the thirteenth aspects, wherein the number of titanium nitride sub-cycles utilized in the process, relative to the number of pulse sequences is pre-determined to provide a titanium silicon nitride film having a desired weight percentage of silicon.

In a sixteenth aspect, the invention provides the process of any one of the eleventh through the fourteenth aspects, wherein the percentage of silicon in the film is about 5 to about 50 weight percent.

In a seventeenth aspect, the invention provides the process of any one of the eleventh through the fourteenth aspects, wherein the percentage of silicon in the film is about 15 to about 35 weight percent.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A process for depositing a titanium silicon nitride film on a microelectronic device substrate in a reaction zone, which comprises:
introducing compounds A, B, and C, individually, into the reaction zone under pulsed vapor deposition conditions to provide a pulse sequence, wherein the reaction zone is about 250° C. to about 450° C.; each compound optionally followed by a purge step with an inert gas, and wherein A is chosen from bis-t-amyl ethylene silylene, SiI₂H₂, and SiI₄; B is TiCl₄; and C is a nitrogen-containing reducing gas, and repeating the pulse sequence until a desired thickness of the film has been deposited.

2. The process of claim 1, wherein the thickness of the titanium silicon nitride film is at least about 10 Å.

3. The process of claim 1, wherein the thickness of the titanium silicon nitride film is at least about 20 Å.

4. The process of claim 1, wherein the thickness of the titanium silicon nitride film is at least about 30 Å.

5. The process of claim 1, wherein the pulsed vapor deposition conditions comprise a plurality of pulse sequences, wherein the pulse sequence comprises a pulse of A, followed by a pulse of B, followed by a pulse of C, each pulse optionally followed by a purge step with an inert gas.

6. The process of claim 1, wherein the pulsed vapor deposition conditions comprise a plurality of pulse sequences, wherein the pulse sequence comprises a pulse of A, followed by a pulse of C, followed by a pulse of B, followed by a pulse of C, each pulse optionally followed by a purge step with an inert gas.

7. The process of claim 1, wherein A is bis-t-amyl ethylene silylene.

8. The process of claim 1, wherein A is SiI₂H₂.

9. The process of claim 1, wherein B is titanium tetrachloride.

10. The process of claim 1, wherein the nitrogen-containing reducing gas is chosen from ammonia; hydrazine; 1,1-dimethyl hydrazine; and 1,2-dimethyl hydrazine.

11. The process of claim 1, wherein the nitrogen-containing reducing gas is ammonia.
The process of claim 1, wherein the pulsed vapor deposition conditions further comprise introduction of B and C to provide a titanium nitride sub-cycle, each of B and C optionally followed by a purge with an inert gas.12.

12. The process of claim 5, further comprising introduction of B and C to provide a titanium nitride sub-cycle, each of B and C optionally followed by a purge with an inert gas.

13. The process of claim 11, wherein B is introduced followed by C

14. The process of claim 11, wherein the number of titanium nitride sub-cycles utilized in the process, relative to the number of pulse sequences is pre-determined to provide a titanium silicon nitride film having a desired weight percentage of silicon.

15. The process of claim 12, wherein the number of titanium nitride sub-cycles utilized in the process, relative to the number of pulse sequences is pre-determined to provide a titanium silicon nitride film having a desired weight percentage of silicon.

16. The process of claim 1, wherein the percentage of silicon in the film is about 5 to about 50 weight percent.

17. The process of claim 1, wherein the percentage of silicon in the film is about 5 to about 50 weight percent.

18. The process of claim 1, wherein the percentage of silicon in the film is about 15 to about 35 weight percent.

19. The process of claim 1, wherein the percentage of silicon in the film is about 15 to about 35 weight percent.
